(19) United States
(12) Patent Application Publication
(10) Pub. No.: US 2026/0368383 A1
(43) Pub. Date: Nov. 19, 2026

(54) THREE-DIMENSIONAL RECONSTRUCTION METHOD, REPAIR METHOD AND DEVICE FOR DAMAGED STRUCTURE

(71) Applicant: CIVIL AVIATION FLIGHT UNIVERSITY OF CHINA, Guanghan (CN)

(72) Inventors: Jianjian ZHU, Guanghan (CN); Wenpeng BAI, Guanghan (CN); Yaoming FU, Guanghan (CN); Meng LI, Guanghan (CN)

(21) Appl. No.: 19/529,569

(22) Filed: Feb. 4, 2026

(30) Foreign Application Priority Data
Apr. 15, 2025 (CN) 202510464717.X

(51) Int. Cl. G06F 30/13; G06T 7/00; G06T 7/73; G06V 10/50; G06V 10/764; G06V 10/82

(52) U.S. Cl. CPC G06F 30/13; G06T 7/001; G06T 7/74; G06T 7/75; G06V 10/507; G06V 10/764; G06V 10/82; G06T 2207/10028; G06T 2207/20081; G06T 2207/20084; G06T 2207/30144

(57) ABSTRACT

The present application discloses a three-dimensional reconstruction method, repair method and device for a damaged structure, which belongs to the technical field of data processing. The reconstruction method includes: obtaining three-dimensional point cloud data of the damaged structure based on a laser scanning device; projecting and converting the three-dimensional point cloud data into a two-dimensional image, and extracting directional gradient features of the two-dimensional image by using a Histogram of Oriented Gradients (HOG) method to obtain HOG features; constructing a gradient field based on the three-dimensional point cloud data, and correcting a gradient field by using the HOG features to obtain a corrected gradient field; reconstructing a three-dimensional model of the damaged structure by using the corrected gradient field combined with a Poisson equation. The present application can improve the accuracy of damage information acquisition, thereby enhancing the reliability of repair.

### CROSS-REFERENCE TO RELATED APPLICATIONS

The present application claims priority to Chinese patent application No. 202510464717.X, filed on Apr. 15, 2025, the entire contents of which are incorporated herein by reference.

### TECHNICAL FIELD

The present application relates to the technical field of data processing, and in particular, to a three-dimensional reconstruction method, repair method and device for a damaged structure.

### BACKGROUND

In the related art, components with structural damage rely on manual visual inspection and simple measuring tools, making it difficult to accurately obtain detailed damage information in the damaged structure, which in turn leads to poor repair reliability.

### SUMMARY

The present application provides a three-dimensional reconstruction method, repair method and device for a damaged structure, which can improve the accuracy of damage information acquisition, thereby enhancing repair reliability. The technical solution is as follows:

In a first aspect, a three-dimensional reconstruction method for a damaged structure is provided, and the method includes:

obtaining three-dimensional point cloud data of the damaged structure based on a laser scanning device;

projecting and converting the three-dimensional point cloud data into a two-dimensional image, and extracting directional gradient features of the two-dimensional image by using a Histogram of Oriented Gradients (HOG) method to obtain HOG features;

constructing a gradient field based on the three-dimensional point cloud data, and correcting the gradient field by using the HOG features to obtain a corrected gradient field;

wherein a correction method comprises:

dividing gradient directions into a plurality of intervals based on the HOG features, and selecting a direction with a maximum amplitude from the plurality of intervals as a main direction;

determining gradient amplitudes of points in a target interval corresponding to the main direction in the gradient field;

comparing and fusing the gradient amplitudes of points in the target interval in the gradient field with the gradient amplitudes of the target interval in the HOG features to obtain a gradient field reflecting real gradient changes of the damaged structure;

reconstructing a three-dimensional model of the damaged structure by using the corrected gradient field combined with a Poisson equation;

wherein a reconstruction process further comprises adjusting initial values of grid points, and an adjustment method comprises:

calculating statistical information of HOG feature vectors of points in a neighborhood of each grid point by using the HOG features;

based on a distribution of the statistical information, if a proportion of gradient amplitudes in a first direction interval calculated in a neighborhood of a target grid point is higher than that in other intervals, and a first direction is close to a gradient direction at a damaged position, further determining that the target grid point is located on a surface of an object, and adjusting an initial value of the target grid point to be closer to 0; and

for a neighborhood of non-target grid points, since the HOG feature vectors are uniformly distributed, adjusting initial values of the non-target grid points to be closer to 1.

In a second aspect, the present application provides a repair method for a damaged structure, which includes:

reconstructing a three-dimensional model of the damaged structure by using any one of the three-dimensional reconstruction methods for the damaged structure;

obtaining a three-dimensional model of an undamaged structure;

determining a three-dimensional model of a repair part for repairing the damaged structure by using the three-dimensional model of the damaged structure and the three-dimensional model of the undamaged structure;

importing the three-dimensional model of the repair part into a three-dimensional printer for three-dimensional printing to obtain a physical repair part for repairing the damaged structure.

In a third aspect, the present application provides a repair device for a damaged structure, which includes:

a first acquisition unit, configured to reconstruct a three-dimensional model of the damaged structure by using any one of the three-dimensional reconstruction methods for damaged structure;

a second acquisition unit, configured to obtain a three-dimensional model of the undamaged structure;

a determination unit, configured to determine a three-dimensional model of a repair part for repairing the damaged structure by using the three-dimensional model of the damaged structure and the three-dimensional model of the undamaged structure; and

an import unit, configured to import the three-dimensional model of the repair part into a three-dimensional printer for three-dimensional printing to obtain a physical repair part for repairing the damaged structure.

In a fourth aspect, the present application provides a three-dimensional reconstruction device for a damaged structure, which includes:

an acquisition unit, configured to obtain three-dimensional point cloud data of the damaged structure based on a laser scanning device;

an extraction unit, configured to project and convert the three-dimensional point cloud data into a two-dimensional image, and extract directional gradient features of the two-dimensional image by using a Histogram of Oriented Gradients (HOG) method to obtain HOG features;

a construction unit, configured to construct a gradient field based on the three-dimensional point cloud data, and correct the gradient field by using the HOG features to obtain a corrected gradient field;

a reconstruction unit, configured to reconstruct a three-dimensional model of the damaged structure by using the corrected gradient field combined with a Poisson equation.

In a fifth aspect, the present application provides a computer device, comprising a memory and a processor, wherein the memory is configured to store a computer program, and the processor is configured to execute the computer program stored on the memory to implement the aforementioned three-dimensional reconstruction method for the damaged structure and the repair method for the damaged structure.

In a sixth aspect, the present application provides a computer-readable storage medium, wherein a computer program is stored in the storage medium, and the computer program implements the aforementioned three-dimensional reconstruction method for the damaged structure and the repair method for the damaged structure when executed by a processor.

In a sixth aspect, the present application provides a computer program product is provided, which includes a computer program that, when executed by a processor, implements the steps of the aforementioned three-dimensional reconstruction method for the damaged structure and the repair method for the damaged structure.

The technical solutions provided by the present application can at least bring the following beneficial effects:

The present application provides a three-dimensional reconstruction method for a damaged structure. When reconstructing the three-dimensional model of the damaged structure, a laser scanning device can be used to accurately obtain the three-dimensional point cloud data of the damaged structure. Two methods are adopted to determine the gradient information of the damaged structure: the first method is to directly construct a gradient field capable of realizing three-dimensional model reconstruction using the three-dimensional point cloud data; the second method is to extract directional gradient features from the two-dimensional image obtained by projecting and converting the three-dimensional point cloud data to obtain HOG features, and then use the HOG features to correct the gradient field, such that the corrected gradient field can more accurately reflect the real gradient changes of the damaged structure, thereby improving the accuracy of the reconstructed three-dimensional model of the damaged structure.

The present application provides a repair method for a damaged structure, which reconstructs an accurate three-dimensional model of the damaged structure by using the aforementioned three-dimensional reconstruction method for the damaged structure, and then can obtain the three-dimensional model of the damaged part (i.e., the three-dimensional model of the repair part for repairing the damaged structure) by using the three-dimensional model of the undamaged structure and the three-dimensional model of the damaged structure. Due to the high accuracy of the reconstructed three-dimensional model of the damaged structure, the three-dimensional model of the repair part can accurately describe the detailed damage information in the damaged structure. Furthermore, after three-dimensional (3D) printing using the three-dimensional model of the repair part, a physical repair part for repairing the damaged structure can be obtained, which improves the repair reliability.

### BRIEF DESCRIPTIONS OF THE DRAWINGS

To explain the technical solutions in the embodiments of the present application or the related art more clearly, the accompanying drawings required for describing the embodiments or the related art will be briefly introduced below. Obviously, the accompanying drawings in the following description are some embodiments of the present application, and those skilled in the art can obtain other accompanying drawings based on these drawings without creative effort.

FIG. 1 is a flowchart of a three-dimensional reconstruction method for a damaged structure according to an embodiment of the present application.

FIG. 2 is a flowchart of a repair method for a damaged structure according to an embodiment of the present application.

FIG. 3 is a structural diagram of a three-dimensional reconstruction device for a damaged structure according to an embodiment of the present application.

FIG. 4 is a structural diagram of a repair device for a damaged structure according to an embodiment of the present application.

FIG. 5 is a hardware architecture diagram of a computer device according to an embodiment of the present application.

### DETAILED DESCRIPTIONS OF EMBODIMENTS

To clarify the objectives, technical solutions, and advantages of the embodiments of the present application, the technical solutions in the embodiments of the present application will be clearly and completely described below in conjunction with the accompanying drawings in the embodiments of the present application. Obviously, the described embodiments are part rather than all of the embodiments of the present application. Based on the embodiments of the present application, all other embodiments obtained by those skilled in the art without creative effort shall fall within the scope of protection of the present application.

As mentioned above, it is difficult to accurately obtain damage information in a damaged structure by means of manual visual inspection and simple measuring tools. Moreover, the Poisson reconstruction method based on the gradient field focuses more on the overall structure and has insufficient sensitivity to local damage.

Based on this, the inventive concept of the present application is to use the Histogram of Oriented Gradients (HOG) method to extract HOG features from the image. Since HOG features are more sensitive to local damage, the HOG features are then used to correct the gradient field. Thus, during the Poisson reconstruction using the gradient field, the reconstructed three-dimensional model can more accurately reflect the real gradient changes in the damaged area, improving the accuracy of the reconstructed three-dimensional model of the damaged structure.

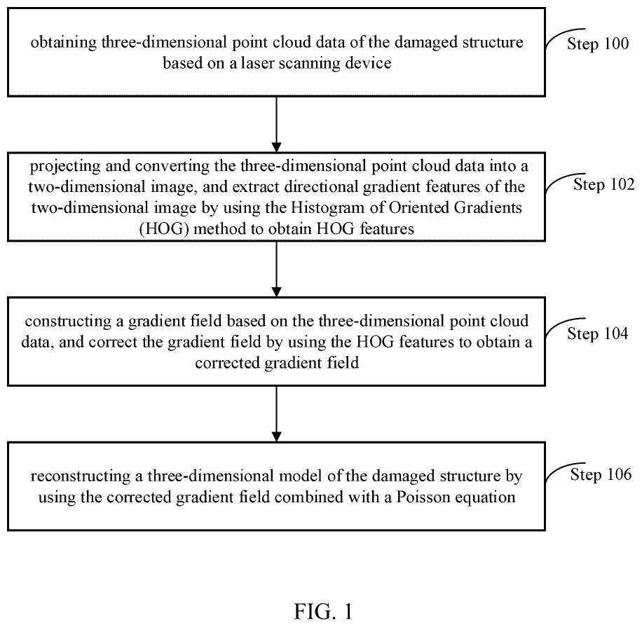

Please refer to FIG. 1, which shows a flowchart of a three-dimensional reconstruction method for a damaged structure provided by an embodiment of the present application. The method includes the following steps:

Step 100: obtaining three-dimensional point cloud data of the damaged structure based on a laser scanning device;

Step 102: projecting and converting the three-dimensional point cloud data into a two-dimensional image, and extract directional gradient features of the two-dimensional image by using the Histogram of Oriented Gradients (HOG) method to obtain HOG features;

Step 104: constructing a gradient field based on the three-dimensional point cloud data, and correct the gradient field by using the HOG features to obtain a corrected gradient field;

Step 106: reconstructing a three-dimensional model of the damaged structure by using the corrected gradient field combined with a Poisson equation.

In the embodiment of the present application, when reconstructing the three-dimensional model of the damaged structure, a laser scanning device is used to accurately obtain the three-dimensional point cloud data of the damaged structure. Two methods are adopted to determine the gradient information of the damaged structure. The first method is to directly construct a gradient field capable of realizing three-dimensional model reconstruction by using the three-dimensional point cloud data. The second method is to extract directional gradient features from the two-dimensional image obtained by projecting and converting the three-dimensional point cloud data to obtain HOG features, and then use the HOG features to correct the gradient field, such that the corrected gradient field can more accurately reflect the real gradient changes of the damaged structure, thereby improving the accuracy of the reconstructed three-dimensional model of the damaged structure.

Before describing the implementation manner of each step shown in FIG. 1, the application scenarios of the embodiment of the present application will be explained first. The application scenarios of the embodiment of the present application at least include damage repair of mechanical parts in the field of mechanical engineering and aviation equipment parts in the field of aerospace. For example, mechanical parts form a damaged structure due to long-term operation or abnormal stress, and aviation equipment parts suffer fatigue or structural damage due to huge aerodynamic forces and structural stresses during flight. When damage occurs in parts, three-dimensional reconstruction is performed on the damaged structure to obtain a three-dimensional model of the repair part for repairing the damaged structure, and the repair part is printed by using three-dimensional (3D) printing technology to realize the repair of the damaged structure.

The implementation manner of each step shown in FIG. 1 is described below.

First, for Step 100: obtaining three-dimensional point cloud data of the damaged structure based on a laser scanning device.

In the embodiment of the present application, a laser scanning device with high resolution can be used, for example, a device with a resolution of 0.1 mm. By comprehensively scanning the damaged structure with the laser scanning device, accurate three-dimensional point cloud data can be obtained, which further provides a data basis for the subsequent three-dimensional model reconstruction of the damaged structure.

Further, to improve data accuracy, the three-dimensional point cloud data scanned by the laser scanning device can be purified to effectively remove interference information such as background objects, improve data purity, and facilitate subsequent steps using the purified three-dimensional point cloud data.

Then, for Step 102: projecting and converting the three-dimensional point cloud data into a two-dimensional image, and extracting directional gradient features of the two-dimensional image by using the HOG method to obtain HOG features.

Gradient features are required for three-dimensional model reconstruction, and three-dimensional model reconstruction can be realized by constructing a gradient field. Considering that there are certain errors in directly constructing a gradient field by using three-dimensional point cloud data, the Histogram of Oriented Gradients method is adopted to extract directional gradient features from the two-dimensional image, so as to realize the correction of the directly constructed gradient field, making the gradient field for three-dimensional model reconstruction more capable of reflecting real gradient changes.

In an embodiment of the present application, considering that the damage types of damaged parts in the damaged structure are different, to enable the corrected gradient field to more accurately restore the features of the damaged parts, the step of extracting directional gradient features of the two-dimensional image by using the HOG method to obtain HOG features may specifically include: extracting features from the two-dimensional image by using an improved fully convolutional network model to output a feature map capable of reflecting the feature pattern corresponding to the damage type; extracting directional gradient features of the feature map by using the HOG method to obtain HOG features.

Since the feature map used for extracting HOG features is a feature map capable of reflecting the feature pattern corresponding to the damage type, and the feature map is obtained by the output of the improved fully convolutional network model, the HOG features extracted from the feature map have more detailed and real gradient information at the damaged parts. Thus, after the gradient field is corrected by using the HOG features, the gradient information of the corrected gradient field at the damaged parts is more accurate, thereby improving the accuracy of three-dimensional model reconstruction.

In the embodiment of the present application, the training method of the improved fully convolutional network model includes:

obtaining a plurality of training samples; the training samples include two-dimensional sample images labeled with damage types; wherein the two-dimensional sample images are obtained by projecting and converting three-dimensional sample point cloud data of sample a damaged structure;

training the fully convolutional network by using the plurality of training samples in a supervised training manner, so that the fully convolutional network learns feature patterns corresponding to different damage types to output feature maps capable of reflecting the feature patterns corresponding to respective damage types, and thus the improved fully convolutional network model is obtained through training.

Since different damage types correspond to different feature patterns, by training the fully convolutional network with two-dimensional sample images labeled with damage types, the fully convolutional network can learn the feature patterns corresponding to different damage types. Thus, in practical application, when extracting features from the input two-dimensional image, the extracted feature map has the feature pattern matching its damage type, and the damage type can be determined based on the feature pattern in the feature map during subsequent extraction of HOG features, making the extracted HOG features more accurate in terms of gradient direction features.

In an embodiment of the present application, the damage types include at least one of cracks, spalling, deformation, corrosion and wear.

In an embodiment of the present application, the architecture of the improved fully convolutional network model and the processing manner of its input two-dimensional image include:

a macro feature extraction layer, configured to quickly extract macro features of the input two-dimensional image to reduce the resolution of the required output feature map; the macro feature extraction layer can be implemented by a convolutional layer with a 7×7 convolution kernel and a stride of 2;

a multi-scale downsampling layer, including pooling layers of different sizes connected in sequence, configured to perform multi-scale downsampling processing on the output of the macro feature extraction layer to capture abstract information of different scales;

an upsampling layer, implemented by a transposed convolutional layer, for example, a transposed convolutional layer with a 4×4 convolution kernel and a stride of 2, configured to gradually restore the resolution of the feature map from the output of the multi-scale downsampling layer;

a plurality of convolution optimization layers, sequentially arranged between the above layers, configured to adjust and optimize feature information;

a multi-scale feature fusion layer, configured to splice and fuse the feature maps of corresponding block levels in downsampling with the feature maps of similar scales after upsampling restoration in the channel dimension according to the division of 8×8 cell units and 2×2 blocks; and

a final output layer, implemented by a 1×1 convolutional layer, configured to output a feature map with the same size as the input two-dimensional image.

The improved fully convolutional network model is trained by using training samples of various different damage types. Therefore, when the improved fully convolutional network model is used to extract features from the input two-dimensional image, the output image has the feature pattern matching its damage type.

Further, after the feature map is obtained, features can be extracted from the feature map by using the HOG method to obtain HOG features. The HOG features can be used as key scanning features in the repair process of damaged parts. The extraction process of HOG features may specifically include:

Step 1: uniformly dividing the feature map into cell units with a size of D1×D1 pixels, where D1 is a positive integer, such as 8×8 cell units;

Step 2: for each cell unit, calculating the gradient amplitude and gradient direction of each pixel in it by using the central difference method;

Step 3: dividing the calculated gradient directions into a plurality of histogram bins, and accumulating the gradient amplitude of each pixel into the corresponding histogram bin according to its gradient direction, thereby constructing a gradient direction histogram for each cell unit;

Step 4: grouping adjacent D2×D2 cell units into a block, and performing L2-norm normalization processing on the gradient direction histograms of the cell units in each block; where D2 is a positive integer, such as 2×2 cell units; and

Step 5: combining the normalized gradient direction histograms of all blocks in a certain order to form a feature vector describing the entire image, and the feature vector is the HOG feature.

Since the feature map has the feature pattern matching its damage type, the extracted HOG features can accurately describe the gradient information at the damaged parts.

Finally, Step 104 “constructing a gradient field based on the three-dimensional point cloud data, and correcting the gradient field by using the HOG features to obtain a corrected gradient field” and Step 106 “reconstructing the three-dimensional model of the damaged structure by using the corrected gradient field combined with the Poisson equation” are explained together.

In the embodiment of the present application, to reconstruct the three-dimensional model of the damaged structure, the Poisson algorithm can be used, which requires constructing a gradient field first to serve as a source term in the Poisson equation, specifically:

Step 1040: preprocessing the three-dimensional point cloud data.

In one implementation manner, an outlier removal method based on distance can be used to calculate the average distance from each point in the three-dimensional point cloud data to its nearest neighbor points, and points with a distance greater than a set multiple of the standard deviation of the average distance are regarded as outliers and then removed. For example, 3 times is set.

Step 1042: calculating the gradient field based on the three-dimensional point cloud data, determining the gradient information by fitting a local surface to estimate the normal vector of the points, and obtaining the gradient field based on the gradient information of all three-dimensional point cloud data.

Further, the gradient field directly constructed by using the three-dimensional point cloud data derives the gradient information of the damaged parts in the damaged structure based on the entire damaged structure, the gradient information has certain errors on the whole. That is to say, no more detailed processing is focused on the damaged parts, resulting in indistinct reflection of details of the damaged parts in the gradient field. However, for repairing the damaged parts, more accurate gradient information is required to obtain the repair part, so that the repair part can fit the damaged parts more closely and improve repair reliability.

Based on this, in the embodiment of the present application, the HOG features obtained in Step 102 are used to correct the gradient field. Since the HOG features are extracted from the feature map with the feature pattern matching the damage type, the HOG features also have features matching the damage type, and the HOG features can better reflect the more detailed gradient information of the damaged parts.

In one implementation manner, the method for correcting the gradient field by using the HOG features may include:

dividing gradient directions into a plurality of intervals based on the HOG features, and selecting a direction with a maximum amplitude from the plurality of intervals as a main direction;

determining gradient amplitudes of points in a target interval corresponding to the main direction in the gradient field; and

comparing and fusing the gradient amplitudes of points in the target interval in the gradient field with the gradient amplitudes of the target interval in the HOG features to obtain a gradient field reflecting real gradient changes of the damaged structure.

In the HOG features, the gradients in certain directions dominate the histogram, so the structures in these directions are more important, and such directions are taken as the main directions. Since the edges of the damaged positions of the damaged structure are irregular, the target interval corresponding to the main direction in the HOG features can be regarded as the damaged positions. Therefore, the gradient amplitudes at the damaged positions are used to compare and fuse with the gradient amplitudes at the corresponding positions of the gradient field, so that the gradient information of the gradient field at the damaged positions can better reflect the real gradient changes.

In one implementation manner, the comparison and fusion can be realized by means of weighted average.

Thus, after the comparison and fusion, the corrected gradient field can not only reflect the gradient changes of the overall structure (derived from the gradient field before correction) at the damaged positions, but also highlight the directionality of the local structure (derived from the fusion result of the HOG features and the gradient field).

The embodiments of the present application have at least the following two effects:

First, the gradient information of the damaged structure is determined by two methods respectively. The first method is the HOG feature extraction method, and the second method is the gradient field construction method. The comparison and fusion of the two methods enable the corrected gradient field to better reflect the real gradient changes of the damaged structure, improving the reconstruction accuracy of the three-dimensional model.

Second, since the HOG features extracted by the first method are obtained from the feature map with the feature pattern matching the damage type, the HOG features can more accurately reflect the gradient information of the damaged parts. After the gradient field in the second method is corrected by using the HOG features, the gradient information of the corrected gradient field at the damaged parts is more real and accurate, which in turn ensures the accuracy of the repair parts in the subsequent repair process.

After the corrected gradient field is obtained, the three-dimensional model reconstruction is completed by using the corrected gradient field and the Poisson equation, specifically:

Step 1060: defining an initial indicator function, dividing the space into discrete grids, and assigning initial values to the grid points according to the three-dimensional point cloud data.

In the embodiment of the present application, when dividing the space into discrete grids, the neighborhood radius r can be determined according to the distribution density of the three-dimensional point cloud data. For each point cloud point Pi, a local neighborhood Ni is constructed with Pi as the center and r as the radius, so that the entire space is covered by these local neighborhoods, completing the discretized representation of the space. This step utilizes the distribution information of the point cloud points to divide the space into local regions centered on the points.

In the embodiment of the present application, when assigning initial values to the grid points, for the grid points in each local neighborhood Ni, the initial values can be set according to the attributes of the point cloud point Pi and the neighborhood information. If Pi is determined to be inside the object (the position state of the point is accurately judged by methods such as connectivity analysis of the point cloud data and the positional relationship with the known structural boundary), the initial value of the grid points in Ni is set to a small positive value, such as 0.1; if Pi is outside the object, the initial value of the grid points in the neighborhood is set to a large positive value, such as 1.0. For the point cloud points close to the object surface, a distance-based linear interpolation function is adopted to calculate the initial value according to the estimated distance from the point to the surface. The closer the distance to the surface, the closer the value is to 0. When the distance is greater than a certain threshold, a fixed value of 0.5 is taken. In this way, by considering the different position conditions of the point cloud points, reasonable initial values are assigned to the grid points to guide the subsequent reconstruction process.

Further, after the initial values assigned to the grid points are obtained based on the above method, to ensure that the initial values are more reasonable and improve the accuracy of the three-dimensional model reconstruction realized by solving the Poisson equation with the initial values, the initial values for solving the Poisson equation are obtained by adjusting based on the HOG features of the points in the neighborhood of each grid point. Specifically, it may include: using the HOG features in Step 102 to calculate the statistical information of the HOG feature vectors of the points in the neighborhood of each grid point, and adjusting the initial values of the grid points according to the distribution of the statistical information.

Specifically, determining the neighborhood range of each grid point, calculating the corresponding HOG feature vector for each point in the neighborhood according to the HOG feature calculation method, and then obtaining the statistical information of the HOG feature vectors of the points in each neighborhood by means of mean value, variance, etc.; based on a distribution of the statistical information, if a proportion of gradient amplitudes in a first direction interval calculated in a neighborhood of a target grid point is higher than that in other intervals, and a first direction is close to a gradient direction at a damaged position, further determining that the target grid point is located on a surface of an object, and adjusting an initial value of the target grid point to be closer to 0; and for a neighborhood of non-target grid points, since the HOG feature vectors are uniformly distributed, adjusting initial values of the non-target grid points to be closer to 1.

In one implementation manner, the adjustment can be performed according to the following formula:

Initial value_{new}=Initial value_{old}×(1−α×Gradient proportion)

α is an adjustment coefficient, and the gradient proportion is the amplitude proportion of the first direction interval.

For example, assuming that in the neighborhood of a certain grid point, the proportion of the gradient amplitude within 0°-20° direction interval is much higher than that in other intervals, and this direction is close to the known damage direction (for example, the difference is not greater than a set value). If the grid point is close to the object surface, its initial value may be adjusted from 0.5 to a value closer to 0, such as 0.2. Because the damage may cause changes in surface features, and the closer to the damaged surface, the closer the value of the indicator function should be to 0. If the distribution of the HOG feature vectors in the neighborhood is more uniform without obvious feature directions, the initial value of the grid point can be appropriately increased to make it closer to the initial value setting outside the object (such as 1.0). If the calculated mean values of each dimension are close, the variance is small, and the distribution of the gradient amplitudes in specific directions is uniform, it indicates that the structural changes in this area are not obvious, and it is more likely to be a normal area. The initial value of the grid point can be adjusted from 0.5 to 0.8.

It should be noted that the adjustment range can be determined according to the degree of change.

Step 1062: solving the Poisson equation by using the initial values to obtain the indicator function value vector.

It should be noted that the method for solving the Poisson equation by using the initial values is a well-known technology in the art, and will not be repeated in this embodiment.

Step 1064: performing surface model extraction based on the indicator function value vector, and obtaining the reconstructed three-dimensional model of the damaged structure through model optimization.

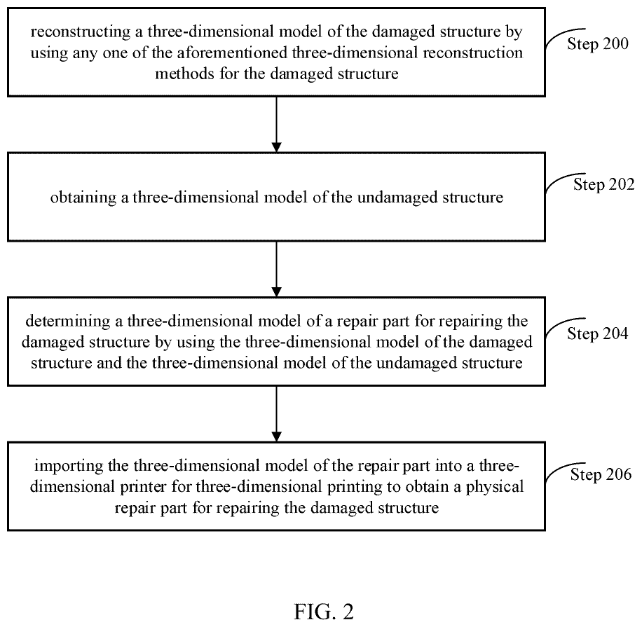

Please refer to FIG. 2, an embodiment of the present application further provides a repair method for a damaged structure, the method may include:

Step 200: reconstructing a three-dimensional model of the damaged structure by using any one of the aforementioned three-dimensional reconstruction methods for the damaged structure;

Step 202: obtaining a three-dimensional model of the undamaged structure;

Step 204: determining a three-dimensional model of a repair part for repairing the damaged structure by using the three-dimensional model of the damaged structure and the three-dimensional model of the undamaged structure; and

Step 206: importing the three-dimensional model of the repair part into a three-dimensional printer for three-dimensional printing to obtain a physical repair part for repairing the damaged structure.

The three-dimensional model of the undamaged structure can be obtained by methods such as historical data calling or symmetric structure generation.

Since the three-dimensional model of the damaged structure has damage, while the three-dimensional model of the undamaged structure is complete and free of damage, the difference between these two three-dimensional models can be calculated to obtain the three-dimensional model of the damaged part, i.e., the three-dimensional model of the repair part for repairing the damaged structure. Importing the three-dimensional model of the repair part into the 3D printer can print out the physical repair part.

It should be noted that after obtaining the three-dimensional model of the repair part, post-processing can be performed on the three-dimensional model of the repair part based on printing requirements, such as adding support structures for 3D printing, adjusting the position and orientation of the model, etc., so as to realize the 3D printing of the repair part.

In the embodiment of the present application, an accurate three-dimensional model of the damaged structure is reconstructed by using the three-dimensional reconstruction method for a damaged structure. Then, by using the three-dimensional model of the undamaged structure and the three-dimensional model of the damaged structure, the three-dimensional model of the damaged part can be obtained, i.e., the three-dimensional model of the repair part for repairing the damaged structure. Due to the high accuracy of the reconstructed three-dimensional model of the damaged structure, the three-dimensional model of the repair part can accurately describe the detailed damage information in the damaged structure. Furthermore, after 3D printing using the three-dimensional model of the repair part, a physical repair part for repairing the damaged structure can be obtained, which improves the repair reliability.

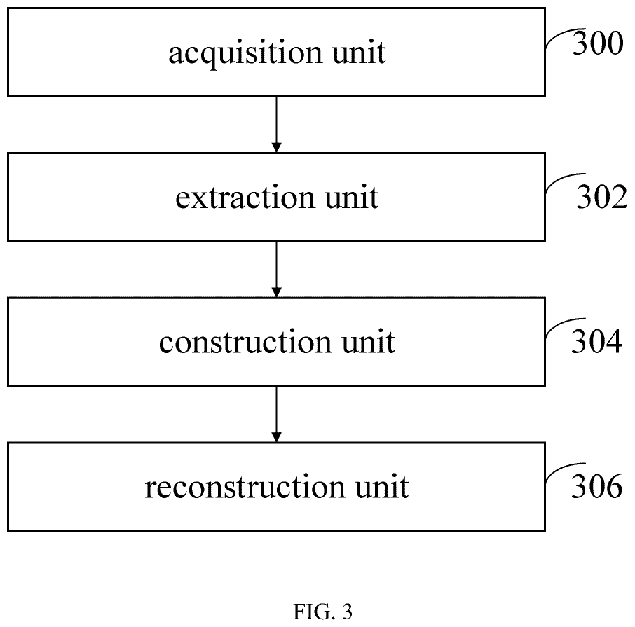

Please refer to FIG. 3, an embodiment of the present application provides a three-dimensional reconstruction device for a damaged structure, the device includes:

an acquisition unit 300, configured to obtain three-dimensional point cloud data of the damaged structure based on a laser scanning device;

an extraction unit 302, configured to project and convert the three-dimensional point cloud data into a two-dimensional image, and extract directional gradient features of the two-dimensional image by using a Histogram of Oriented Gradients (HOG) method to obtain HOG features;

a construction unit 304, configured to construct a gradient field based on the three-dimensional point cloud data, and correct the gradient field by using the HOG features to obtain a corrected gradient field; and

a reconstruction unit 306, configured to reconstruct a three-dimensional model of the damaged structure by using the corrected gradient field combined with a Poisson equation.

In an embodiment of the present application, the extraction unit is specifically configured to extract features from the two-dimensional image by using an improved fully convolutional network model to output a feature map capable of reflecting the feature pattern corresponding to the damage type; extract directional gradient features of the feature map by using the HOG method to obtain HOG features.

In an embodiment of the present application, the training method of the improved fully convolutional network model includes:

obtaining a plurality of training samples; the training samples include two-dimensional sample images labeled with damage types; wherein the two-dimensional sample images are obtained by projecting and converting three-dimensional sample point cloud data of sample damaged structures;

training the fully convolutional network by using the plurality of training samples in a supervised training manner, so that the fully convolutional network learns feature patterns corresponding to different damage types to output feature maps capable of reflecting feature patterns corresponding to respective damage types, and thus the improved fully convolutional network model is obtained through training.

In an embodiment of the present application, the damage types include at least one of cracks, spalling, deformation, corrosion and wear.

In an embodiment of the present application, the initial values for solving the Poisson equation are obtained by adjusting based on the HOG features of the points in the neighborhood of each grid point.

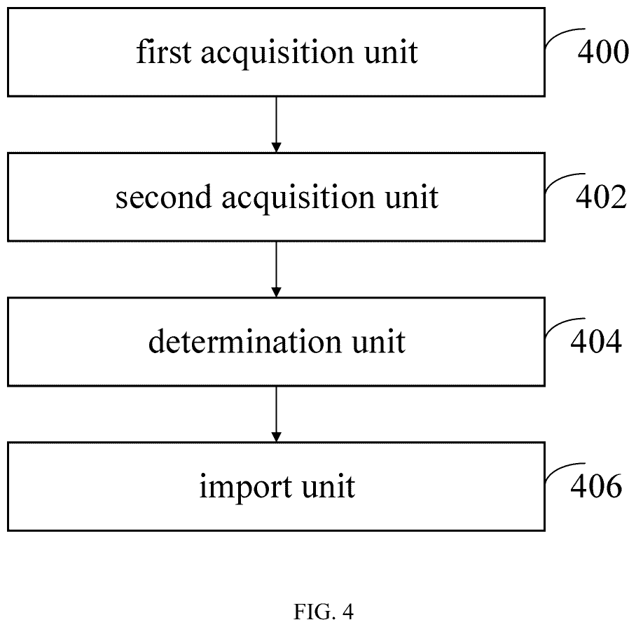

Please refer to FIG. 4, an embodiment of the present application provides a repair device for a damaged structure, the device includes:

a first acquisition unit 400, configured to reconstruct a three-dimensional model of the damaged structure by using any one of the aforementioned three-dimensional reconstruction methods for the damaged structure;

a second acquisition unit 402, configured to obtain a three-dimensional model of the undamaged structure;

a determination unit 404, configured to determine a three-dimensional model of a repair part for repairing the damaged structure by using the three-dimensional model of the damaged structure and the three-dimensional model of the undamaged structure;

an import unit 406, configured to import the three-dimensional model of the repair part into a three-dimensional printer for three-dimensional printing to obtain a physical repair part for repairing the damaged structure.

It should be noted that the three-dimensional reconstruction device and the repair device for the damaged structure provided in the above embodiments are only illustrated by the division of the above functional modules. In practical applications, the above functions can be allocated to different functional modules according to needs, i.e., the internal structure of the device is divided into different functional modules to complete all or part of the functions described above. In addition, the three-dimensional reconstruction device for the damaged structure provided in the above embodiments and the three-dimensional reconstruction method for the damaged structure belong to the same concept, and the specific implementation process is detailed in the method embodiment, which will not be repeated here. Similarly, the repair device for the damaged structure provided in the above embodiments and the repair method for the damaged structure belong to the same concept, and the specific implementation process is detailed in the method embodiment, which will not be repeated here.

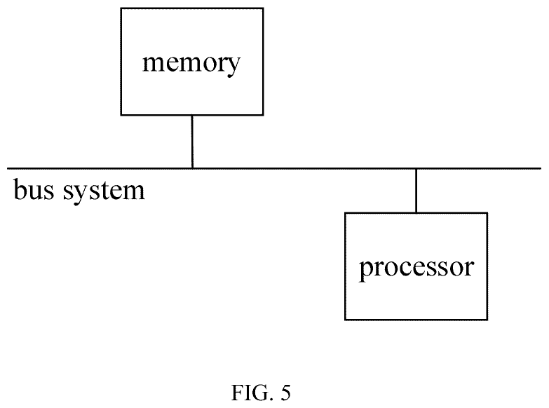

Embodiments of the present application also provide a computer device, please refer to FIG. 5, the computer device includes a processor and a memory, where at least one instruction, at least one segment of program, code set or instruction set is stored in the memory, and the at least one instruction, at least one segment of program, code set or instruction set is loaded and executed by the processor to implement the three-dimensional reconstruction method for the damaged structure and the repair method for the damaged structure provided in the above method embodiments.

Embodiments of the present application also provide a computer-readable storage medium, where at least one instruction, at least one segment of program, code set or instruction set is stored on the computer-readable storage medium, and the at least one instruction, at least one segment of program, code set or instruction set is loaded and executed by a processor to implement the three-dimensional reconstruction method for the damaged structure and the repair method for the damaged structure provided in the above method embodiments.

Embodiments of the present application also provide a computer program product, the computer program product includes a computer program, the processor of the computer device reads the computer program from the computer-readable storage medium, and the processor executes the computer program, so that the computer device executes any one of the three-dimensional reconstruction method for the damaged structure and the repair method for the damaged structure described in the above embodiments.

For the convenience of description, the above system or device is described by dividing various modules or units according to functions. Of course, in the implementation of the present application, the functions of each unit can be implemented in one or more pieces of software and/or hardware.

From the description of the above embodiments, those skilled in the art can clearly understand that the present application can be implemented by means of software plus a necessary universal hardware platform. Based on such an understanding, the technical solution of the present application, which is essentially or makes contributions to the prior art, can be embodied in the form of a software product. The computer software product can be stored in a storage medium, such as ROM/RAM, magnetic disk, optical disk, etc., and includes several instructions to enable a computer device (which may be a personal computer, a server, or a network device, etc.) to execute the methods described in various embodiments or some parts of the embodiments of the present application.

Finally, it should also be noted that in this document, relational terms such as first, second, third, fourth, etc., are only used to distinguish one entity or operation from another entity or operation, and do not necessarily require or imply that there is any such actual relationship or order between these entities or operations. Moreover, the terms “include”, “comprise” or any other variants thereof are intended to cover non-exclusive inclusion, so that a process, method, article or device including a series of elements not only includes those elements, but also includes other elements not explicitly listed, or further includes elements inherent to such a process, method, article or device. Without more constraints, an element defined by the sentence “including one . . . ” does not exclude the existence of other identical elements in the process, method, article or device including the element.

The above descriptions are only the preferred embodiments of the present application. It should be pointed out that for those skilled in the art, several improvements and modifications can be made without departing from the principles of the present application, and these improvements and modifications should also be regarded as the protection scope of the present application.

What is claimed is:

1. A three-dimensional reconstruction method for a damaged structure, comprising:
obtaining three-dimensional point cloud data of the damaged structure based on a laser scanning device;
projecting and converting the three-dimensional point cloud data into a two-dimensional image, and extracting directional gradient features of the two-dimensional image by using a Histogram of Oriented Gradients (HOG) method to obtain HOG features;
constructing a gradient field based on the three-dimensional point cloud data, and correcting the gradient field by using the HOG features to obtain a corrected gradient field;
wherein a correction method comprises:
dividing gradient directions into a plurality of intervals based on the HOG features, and selecting a direction with a maximum amplitude from the plurality of intervals as a main direction;
determining gradient amplitudes of points in a target interval corresponding to the main direction in the gradient field;
comparing and fusing the gradient amplitudes of points in the target interval in the gradient field with the gradient amplitudes of the target interval in the HOG features to obtain a gradient field reflecting real gradient changes of the damaged structure;
reconstructing a three-dimensional model of the damaged structure by using the corrected gradient field combined with a Poisson equation;
wherein a reconstruction process further comprises adjusting initial values of grid points, and an adjustment method comprises:
calculating statistical information of HOG feature vectors of points in a neighborhood of each grid point by using the HOG features;
based on a distribution of the statistical information, if a proportion of gradient amplitudes in a first direction interval calculated in a neighborhood of a target grid point is higher than that in other intervals, and a first direction is close to a gradient direction at a damaged position, further determining that the target grid point is located on a surface of an object, and adjusting an initial value of the target grid point to be closer to 0; and
for a neighborhood of non-target grid points, since the HOG feature vectors are uniformly distributed, adjusting initial values of the non-target grid points to be closer to 1.

2. The method according to claim 1, wherein a step of extracting directional gradient features of the two-dimensional image by using HOG method to obtain HOG features comprises:
extracting features from the two-dimensional image by using an improved fully convolutional network model to output a feature map capable of reflecting a feature pattern corresponding to a damage type;
extracting directional gradient features of the feature map by using the HOG method to obtain HOG features;
wherein a training method of the improved fully convolutional network model comprises:
obtaining a plurality of training samples, wherein the training samples comprise two-dimensional sample images labeled with damage types;
wherein the two-dimensional sample images are obtained by projecting and converting three-dimensional sample point cloud data of sample damaged structures;
training the fully convolutional network by using the plurality of training samples in a supervised training manner, so that the fully convolutional network learns feature patterns corresponding to different damage types to output feature maps capable of reflecting feature patterns corresponding to respective damage types, and thus the improved fully convolutional network model is obtained through training.

3. The method according to claim 2, wherein the damage types comprise at least one of cracks, spalling, deformation, corrosion and wear.

4. The method according to claim 1, wherein the initial values for solving the Poisson equation are obtained by adjusting based on HOG features of points in the neighborhood of each grid point.

5. A repair method for a damaged structure, comprising:
reconstructing a three-dimensional model of the damaged structure by using the three-dimensional reconstruction method for the damaged structure according to claim 1;
obtaining a three-dimensional model of an undamaged structure;
determining a three-dimensional model of a repair part for repairing the damaged structure by using the three-dimensional model of the damaged structure and the three-dimensional model of the undamaged structure;
importing the three-dimensional model of the repair part into a three-dimensional printer for three-dimensional printing to obtain a physical repair part for repairing the damaged structure.

6. A three-dimensional reconstruction device for a damaged structure, comprising:
an acquisition unit, configured to obtain three-dimensional point cloud data of the damaged structure based on a laser scanning device;
an extraction unit, configured to project and convert the three-dimensional point cloud data into a two-dimensional image, and extract directional gradient features of the two-dimensional image by using a Histogram of Oriented Gradients (HOG) method to obtain HOG features;
a construction unit, configured to construct a gradient field based on the three-dimensional point cloud data, and correct the gradient field by using the HOG features to obtain a corrected gradient field;
wherein a correction method comprises:
dividing gradient directions into a plurality of intervals based on the HOG features, and selecting a direction with a maximum amplitude from the plurality of intervals as a main direction;
determining gradient amplitudes of points in a target interval corresponding to the main direction in the gradient field;
comparing and fusing the gradient amplitudes of points in the target interval in the gradient field with the gradient amplitudes of the target interval in the HOG features to obtain a gradient field reflecting real gradient changes of the damaged structure;
a reconstruction unit, configured to reconstruct a three-dimensional model of the damaged structure by using the corrected gradient field combined with a Poisson equation;
the reconstruction process further comprises adjusting initial values of grid points, and
wherein an adjustment method comprises:
calculating statistical information of HOG feature vectors of points in a neighborhood of each grid point by using the HOG features;
based on a distribution of the statistical information, if a proportion of gradient amplitudes in a first direction interval calculated in a neighborhood of a target grid point is higher than that in other intervals, and a first direction is close to a gradient direction at a damaged position, further determining that the target grid point is located on a surface of an object, and adjusting an initial value of the target grid point to be closer to 0; and
for a neighborhood of non-target grid points, since the HOG feature vectors are uniformly distributed, adjusting initial values of the non-target grid points to be closer to 1.

7. A repair device for a damaged structure, comprising:
a first acquisition unit, configured to reconstruct a three-dimensional model of the damaged structure by using the three-dimensional reconstruction method for the damaged structure according to claim 1;
a second acquisition unit, configured to obtain a three-dimensional model of the undamaged structure;
a determination unit, configured to determine a three-dimensional model of a repair part for repairing the damaged structure by using the three-dimensional model of the damaged structure and the three-dimensional model of the undamaged structure; and
an import unit, configured to import the three-dimensional model of the repair part into a three-dimensional printer for three-dimensional printing to obtain a physical repair part for repairing the damaged structure.

8. A computer device, comprising a memory and a processor, wherein the memory is configured to store a computer program, and the processor is configured to execute the computer program stored on the memory to implement the method according to claim 1.

9. A computer-readable storage medium, wherein a computer program is stored in the storage medium, and the computer program implements the method according to claim 1 when executed by a processor.
